(19) United States
(12) Patent Application Publication
(10) Pub. No.: US 2026/0282245 A1
(43) Pub. Date: Sep. 17, 2026

(54) Housing for an Electronic Circuitry Assembly

(71) Applicant: VEONEER SWEDEN SAFETY SYSTEMS AB, Stockholm (SE)

(72) Inventor: Jeremy LETUVE, Cergy-Pontoise (FR)

(21) Appl. No.: 19/480,087

(22) PCT Filed: Apr. 9, 2024
(86) PCT No.: PCT/EP2024/059583

§ 371 Date: Oct. 30, 2025

(30) Foreign Application Priority Data
May 2, 2023 (EP) 23170940.3

(51) Int. Cl. H05K 5/00

(52) U.S. Cl. CPC H05K 5/0026

(57) ABSTRACT

A housing (3) for an electronic circuitry assembly (1) is defined by a housing cover (4) and a base plate (6). The base plate (6) has at least two outer reinforcement ribs (9) at an inner surrounding rim (10). A surrounding sidewall (5) of the housing cover (4) sits with a free end (8) of the surrounding sidewall (5) on the base plate (6) between the at least two outer reinforcement ribs (9) and the inner surrounding rim (10), thereby defining a gap (7) between the free end (8) of the surrounding sidewall (5) on the base plate (6). A plurality of openings (11) is formed in the base plate (6). The openings (11) are placed between the at least two outer reinforcement ribs (9) and the inner surrounding rim (10) of the base plate (6). The free end (8) of the surrounding sidewall (5) covers the openings (11) at least partially.

### FIELD OF THE INVENTION

The invention relates to a housing for an electronic circuitry assembly. In particular, the invention relates to a housing for an electronic circuitry assembly being defined by a housing cover and a base plate, the base plate having at least two outer reinforcement ribs at an inner surrounding rim, a surrounding sidewall of the housing cover sitting with a free end of the surrounding sidewall on the base plate between the at least two outer reinforcement ribs and the inner surrounding rim, thereby defining a gap between the free end of the surrounding sidewall on the base plate.

### DESCRIPTION OF THE BACKGROUND ART

Electronic control units (ECUs) today consist of a housing and a base plate that are assembled. These ECUs are often subject to waterproofness requirements from customers, for example IPx3, which is a water aspersion test with water jets, as ECUs must also be waterproof in later use. There is usually a gap between the housing and the base plate to compensate for manufacturing tolerances. Water can flow through the gap between the housing and the base plate into the ECU.

Therefore, water ingress problems can occur with this conventional construction design, as water accumulates between the base plate and the housing during IPx3 water testing. Water accumulates on the top side of the base plate because it cannot drain away quickly enough. A lake of water forms which cannot escape. Due to the natural effect of “capillarity”, the water “climbs” between the housing and the base plate, i.e. the water level rises all around the ECU until it reaches the electronics of the ECU, e.g. a printed circuit board (PCB), and water eventually enters the control unit, causing damage to the electronics (short circuits, failures).

US Patent Application US 2020/0187374 discloses a control box including a water resistant seal. A cover has a plurality of ribs and is configured to be fastened to the housing to cover the opening such the plurality of ribs are sealingly engaged against the seal land.

### SUMMARY OF THE INVENTION

It is an object of the present invention to provide a housing for an electronic circuitry assembly, which housing provides protection of the electronic circuitry assembly from possible water ingress and can be mounted to a body part of the electronic circuitry assembly.

The above object is achieved by a housing for an electronic circuitry assembly according to the features of claim 1.

In an embodiment of the housing for an electronic circuitry assembly, the housing is defined by a housing cover and a base plate. The base plate has at least two outer reinforcement ribs at an inner surrounding rim. A surrounding sidewall of the housing cover sits with a free end of the surrounding sidewall on the base plate between the at least some two outer reinforcement ribs and the inner surrounding rim, thereby defining a gap between the free end of the surrounding sidewall on the base plate. A plurality of openings is formed in the base plate. The openings are placed between the at least two outer reinforcement ribs and the inner surrounding rim of the base plate. The free end of the surrounding sidewall covers the openings at least partially.

The advantage of such a housing is that the openings in the base plate prevent water from accumulating on the top side of the base plate, since the water can discharge through the openings. Thus, the housing provides protection of the electronic circuitry assembly from possible water ingress and can be mounted to a body part of the electronic circuitry assembly.

In an embodiment of the housing, the openings are distributed around the inner surrounding rim of the base plate.

In an embodiment of the housing, the free end of the surrounding sidewall has a peripheral profile. The peripheral profile may be plain or have a groove formed therein. The openings may be formed by a punching process.

The openings may have an oblong form, a rectangular form, or a round form.

In an embodiment of the housing, the electronic circuitry assembly is an electronic control unit (ECU). It is obvious to a person skilled in the art that the present invention is not limited to a housing for an ECU as an electronic circuitry assembly.

### BRIEF DESCRIPTION OF THE DRAWINGS

The numerous advantages of the disclosure may be better understood by those skilled in the art by reference to the accompanying figures in which:

FIG. 1 shows a perspective and partially cut away view of a prior art assembly of housing for an ECU.

FIG. 2 is a detailed perspective view of the mount of the housing cover to the base plate of FIG. 1.

FIG. 3 shows a detailed perspective view of a water accumulation on the top side of the prior art base plate of FIG. 1.

FIG. 4 shows a perspective sectional view of the water ingress into the prior art housing of FIG. 1.

FIG. 5 shows a perspective top view of the prior art base plate of FIG. 1.

FIG. 6 shows a perspective top view of an embodiment of the base plate with oblong openings according to the present invention.

FIG. 7 is a top view of the embodiment shown in FIG. 6.

FIG. 8 is a sectional view of of the openings shown in FIG. 7 and the related water flow through the opening.

FIG. 9 shows a top view of an oblong profile of the opening of FIGS. 6 to 8.

FIG. 10 shows a top view of another embodiment of the opening having a rectangular profile according to the present invention.

FIG. 11 shows another embodiment of the base plate with round openings according to the present invention.

FIG. 12 is a sectional view of one of the round openings shown in FIG. 11 and the associated water discharge through the round opening.

FIG. 13 is a sectional view of an embodiment showing the positioning of a free end of the sidewall of the housing cover and an opening in the base plate.

FIG. 14 is a sectional view of a further embodiment of the free end of the sidewall of the housing cover which is positioned in relation to an opening in the base plate.

### DETAILED DESCRIPTION

In the ensuing description, numerous specific details are provided to enable maximum understanding of the embodiments that are provided by way of example. The embodiments may be implemented with or without specific details, or else with other methods, components, materials, etc. In other circumstances, well-known structures, materials, or operations are not illustrated or described in detail so that various aspects of the embodiments will not be obscured. Reference in the course of the present description to “an embodiment” or “one embodiment” means that a particular structure, peculiarity, or characteristic described in connection with its implementation is comprised in at least one embodiment. Hence, phrases such as “in an embodiment” or “in one embodiment” that may recur in various points of the present description do not necessarily refer to one and the same embodiment. Furthermore, the particular structures, peculiarities, or characteristics may be combined in any convenient way in one or more embodiments.

Same reference numerals refer to same elements or elements of similar function throughout the various figures. Furthermore, only reference numerals necessary for the description of the respective figure are shown in the figures. The shown embodiments represent only examples of how the invention can be carried out. This should not be regarded as a limitation of the invention.

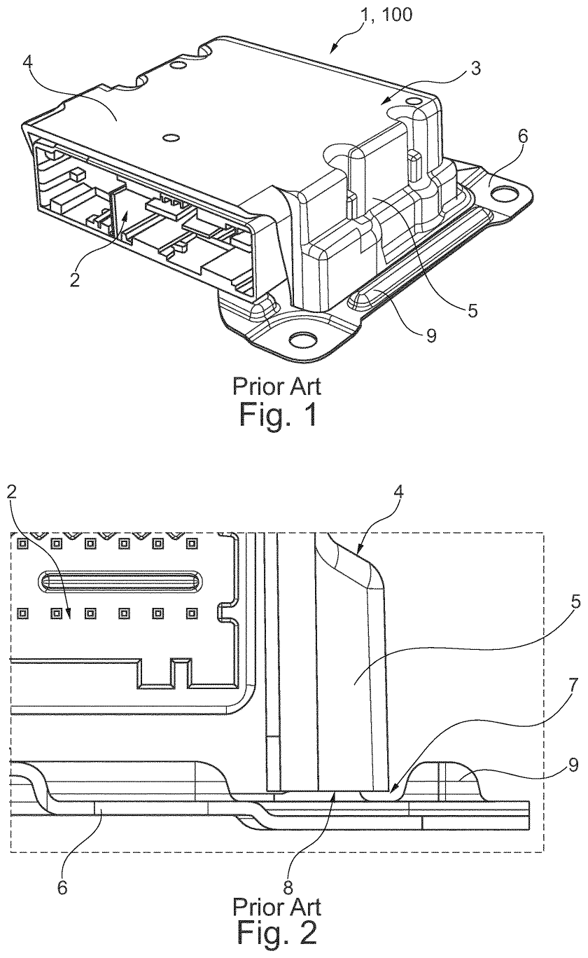

FIG. 1 shows a perspective and partially cut away view of a prior art assembly of a housing 3 for an ECU 100. It is obvious to a person skilled in the art that the housing 3 may be used not only for an ECU 100 as an electronic circuitry assembly, but also for other types of electronic circuitry assemblies. The present invention (see FIG. 6 ff) is applicable to any housing 3 which requires protection of an electronic circuitry assembly 1 from water ingress and can be mounted to a body part (not shown) of the electronic circuitry assembly 1. Housing 3 is defined by a housing cover 4 and a base plate 6. Housing cover 4 rests on base plate 6, and base plate 6 has at least two outer reinforcement ribs 9.

FIG. 2 is a detailed perspective view of housing cover 4, which is mounted to base plate 6 to form housing 3, as shown in FIG. 1. Housing cover 4 has a surrounding sidewall 5 which forms a gap 7 in the mounted state between surrounding sidewall 5 of housing 3 and base plate 6 of housing 3. Gap 7 is used to compensate for manufacturing tolerances.

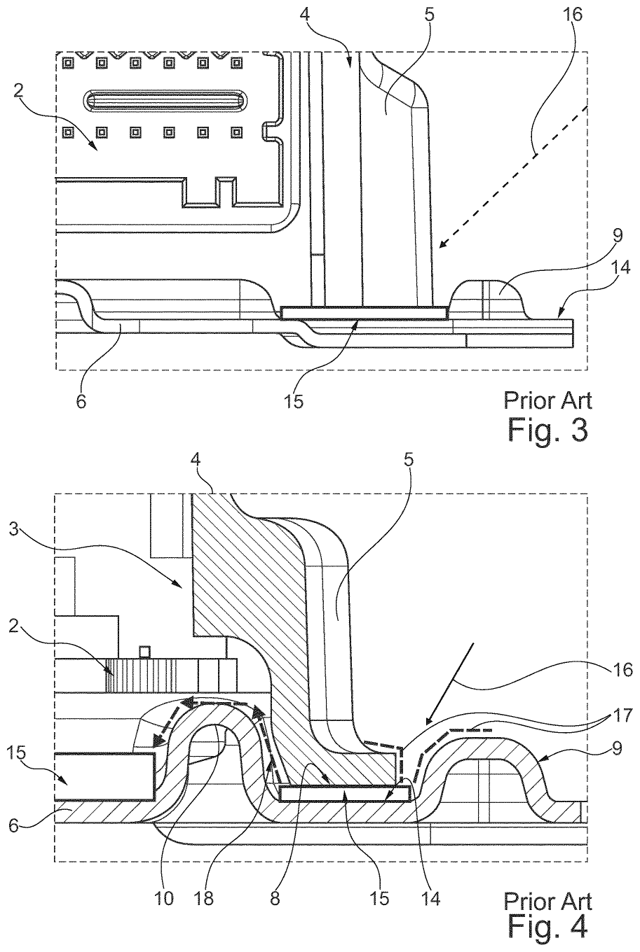

FIG. 3 shows a detailed perspective view of an accumulation of water 15 on the top side 14 of base plate 6 of prior art housing 3, as shown in FIG. 1. The conventional housing 3, defined by the assembled housing cover 4 and the base plate 6, is subject to water ingress problems. During the water testing process, in which water jets 16 are directed onto base plate 6, water 15 accumulates on top side 14 of base plate 6. Water 15 accumulates on top side 14 because it cannot drain away quickly enough. Thus, the water level around housing cover 4 all around the ECU 100 rises and can reach electronics 2 enclosed by housing cover 4 and base plate 6 (see FIG. 4 for more details).

FIG. 4 shows a perspective sectional view of the water ingress into housing 3 of prior art. During the water testing process, water flows 17 are directed onto the top side 14 of base plate 6. The water 15 collects between the free end 8 of sidewall 5 and the top side 14 of base plate 8 and is confined between the inner surrounding rim 10 and the outer reinforcement rib 9. The natural effect of a capillary effect 18 causes the water 15 to climb and rise between the housing 3 and the base plate 6 and above the inner surrounding rim 10 to the base plate 6. The level of water 15 inside inner surrounding rim 10 may rise until it reaches the electronics 2, which may include a printed circuit board (PCB) and electrical pins. A lake of water 15 forms between the inner surrounding rim 10 and the outer reinforcement rib 9, and the water 15 cannot escape. Water 15 then flows through gap 7 between housing 3 and base plate 6 further into the ECU 100 and can here reach the electronics 2 enclosed by housing cover 4 and base plate 6. The water 15 may cause damages to the electronics 2, for example short-circuits and/or other failures.

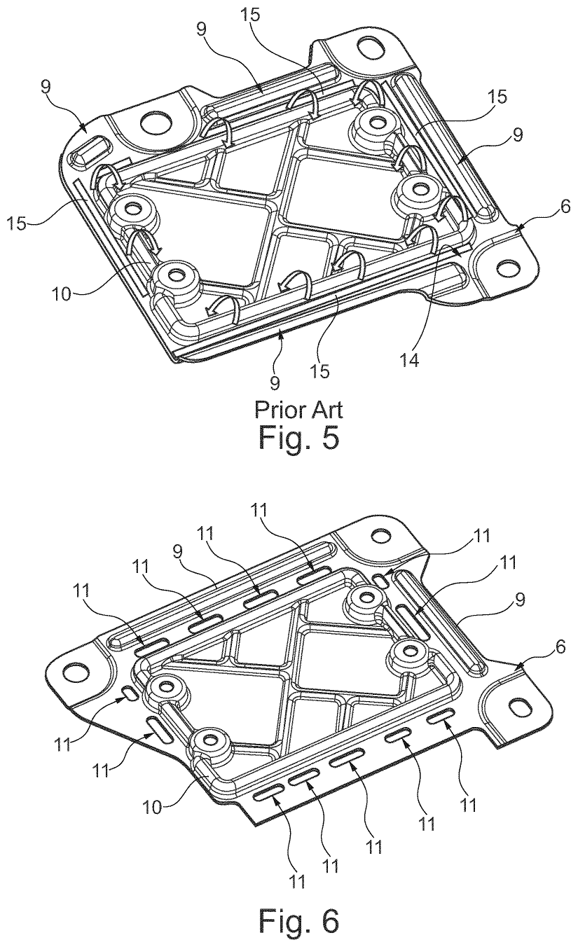

FIG. 5 shows a perspective top view of the prior art base plate 6, the arrows showing the flow and ingress of water 15 into an area inside the inner surrounding rim 10. The water 15 collects primarily outside the inner surrounding rim 10 and partially between the outer reinforcement ribs 9 and the inner surrounding rim 10. The reinforcement ribs 9 of base plate 6 act as a barrier to trap the water 15. However, the reinforcement ribs 9 are necessary for the base plate 6 to have an acceptable rigidity. Described below is the idea of the invention that while water 15 cannot be prevented from reaching this interface between the housing 3 and the base plate 6, the water can be “helped” to escape more quickly to prevent accumulation.

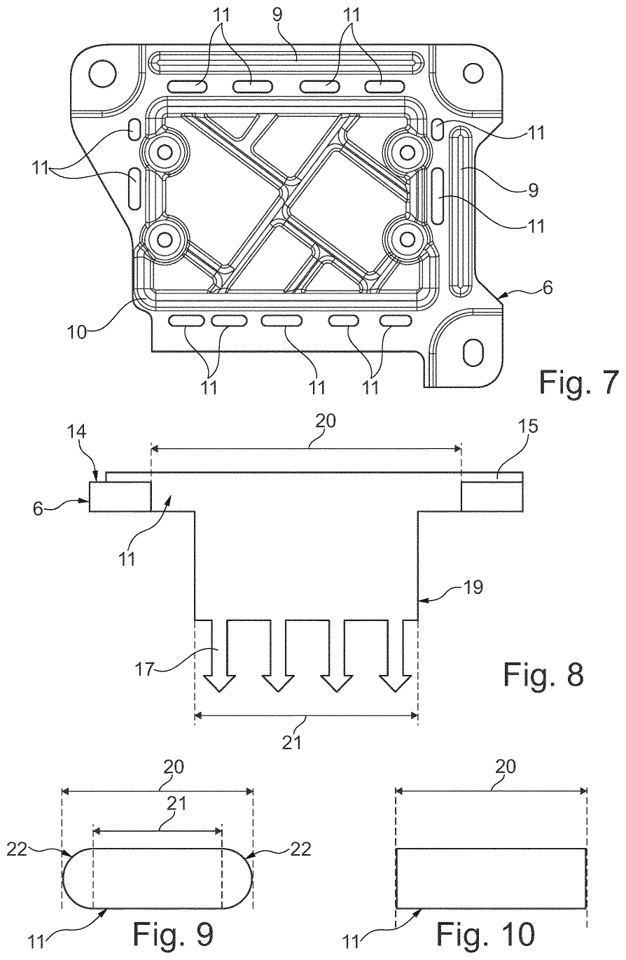

FIG. 6 shows a perspective top view of an embodiment of the base plate 6, and FIG. 7 shows a top view of this embodiment according to the present invention. Note that it is obvious to a person skilled in the art that the present invention is not limited to a housing 3 for an ECU 100 (see FIG. 1) as an electronic circuitry assembly. Therefore, the present invention is applicable to any housing 3 which requires protection of an electronic circuitry assembly 1 (e.g., ECU 100) from water ingress and can be mounted to a body part (not shown) of the electronic circuitry assembly 1. According to this embodiment of the present invention, oblong openings 11 are formed in base plate 6. The oblong openings 11 surround the inner surrounding rim 10 and are partially formed between the outer reinforcement ribs 9 and the inner surrounding rim 10. The oblong openings 11 do not necessarily have the same length 20 (see FIG. 8). The length 20 may vary based on the position of the openings 11 on base plate 6.

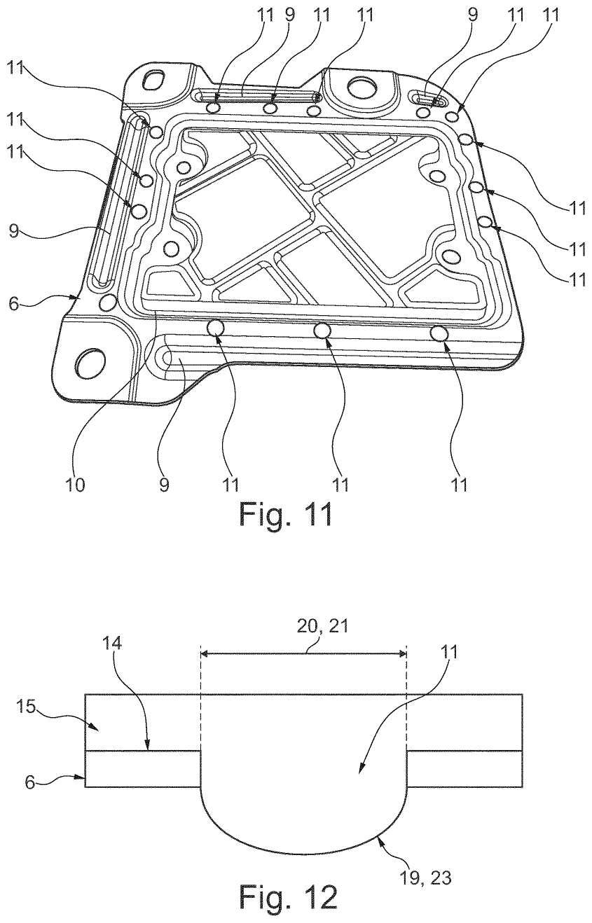

FIG. 8 is a sectional view of one of the openings 11 shown in FIG. 7 and the associated water flow 17 through the opening 11. The openings 11 shown in FIG. 6 and FIG. 7 have an oblong form. The oblong openings 11 prevent water 15 from accumulating on the top side 14 of base plate 6. The oblong openings 11 have a length 20 and an effective length 21. The effective length 21 of the oblong openings 11 does not include the rounded end shapes 22 (see FIG. 9) of the oblong openings 11. Because of the effective length 21 of the oblong openings 11, surface tension does not build up, and water discharge 19 through the oblong openings 11 results in a nearly continuous flow of water 15. Oblong openings 11 prevent the water 15 from forming “plugs” in the oblong openings 11, unlike the classic round opening 11 (see FIGS. 11 and 12). As a result, water 15 has no other choice but rather quickly fall downwardly through the oblong openings 11, and thus water 15 does not have time to accumulate onto the base plate 6, so that the water level does not rise too much and the water 15 cannot flow into the ECU 100.

FIG. 9 shows a top view of an oblong profile of the opening 11 of FIGS. 6 to 8. As mentioned above, a single oblong opening 11 has rounded end shapes 22 defining the longer length 20 and the shorter effective length 21.

FIG. 10 shows a top view of another embodiment of the opening 11 having a rectangular profile according to the present invention. The rectangular openings 11 further increase the water discharge 19 because the influence of surface tension is further reduced, and the length 20 of the opening 11 is effective for the water discharge 19.

FIG. 11 shows another embodiment of the base plate 6 with round openings 11 according to the present invention. The round openings 11 are formed in the base plate 6 and surround the inner surrounding rim 10. The openings 11 are formed between the outer reinforcement ribs 9 and the inner surrounding rim 10. FIG. 12 shows a sectional view of one of the round openings 11 of FIG. 11 and the associated water discharge 19 through the round opening 11. The round opening 11 defines a diameter 20. Here, the round openings 11 tend to trap the water 15 for a relatively long time (compared to oblong or rectangular openings 11) due to surface tension, allowing a drop 23 to form substantially below the opening 11 before the water drop 23 drops overcomes the water surface tension due to its weight and falls. The water drop 23 acts like a “plug” (natural phenomenon), so that the formation of the water drop 23 gives the water 15 time to accumulate on the top side 14 of base plate 6 and the water 15 can climb up to the PCB and flow inside the ECU 100. Hence, compared to the embodiments of the openings 11 with oblong or rectangular openings 11 shown in FIG. 9 and FIG. 10, the water discharge 19 through round openings 11 acts only dropwise and is weak, and the water 15 accumulates at a greater level on the base plate 6 with the round openings 11 in FIGS. 11 and 12.

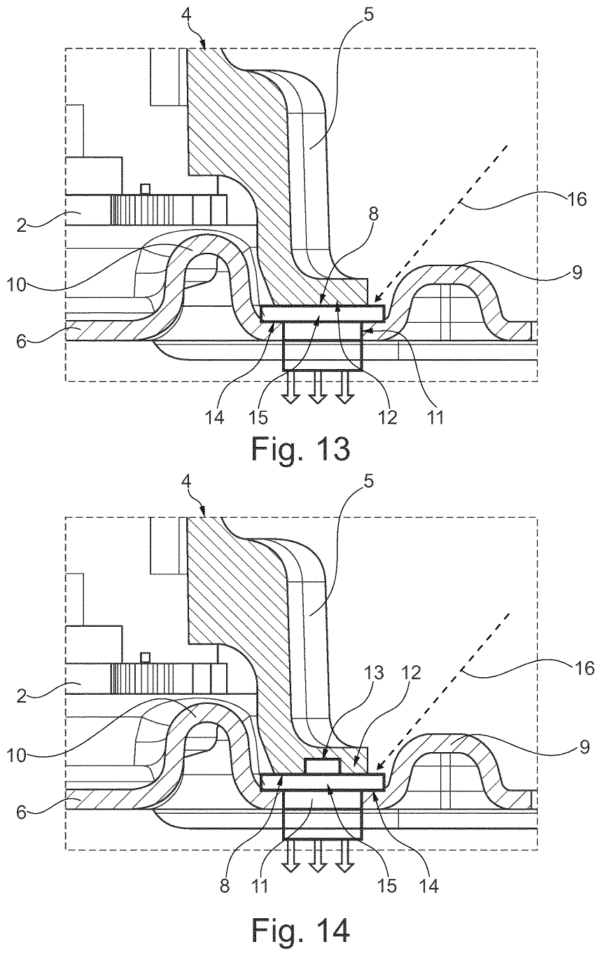

FIG. 13 is a sectional view of an embodiment showing the positioning of a free end 8 of the sidewall 5 of housing cover 4. The free end 8 is positioned opposite to the top side 14 of base plate 6, which is located between the outer reinforcement ribs 9 and the inner surrounding rim 10. The free end 8 defines a peripheral profile 12 which has a flat form and is positioned largely above the opening 11 in the base plate 6. The applied water jet 16 causes water 15 to accumulate on the top side 14 of base plate 6 and between the flat free end 8 of sidewall 5 of housing cover 4. The water 15 is discharged through the opening 11 and does not affect the electronics 2. FIG. 14 is a sectional view of a further embodiment of the free end 8 of sidewall 5 of housing cover 4. Here, a groove 13 is formed in the flat free end 8 of sidewall 5. Groove 13 and the remainder of the flat portion of the free end 8 are located above the opening 11 in base plate 6. The formation of groove 13 in the peripheral profile 12 of the free end 8 of housing cover 4 causes the water 15 to collect directly above the opening 11. In this way, groove 13 forms a buffer that slows down water jet 16 so that it falls faster through oblong opening 11.

It is believed that the present disclosure and many of its attendant advantages will be understood by the foregoing description, and it will be apparent that various changes may be made in the form, construction, number and arrangement of the components without departing from the disclosed subject matter or without sacrificing all of its material advantages. The form described is merely explanatory, and it is the intention of the following claims to encompass and include such changes. Accordingly, the scope of the invention should be limited only by the claims appended hereto.

### LIST OF REFERENCE NUMERALS

1 Electronic circuitry assembly
2 Electronics
3 Housing
4 Housing cover
5 Sidewall
6 Base plate
7 Gap
8 Free end
9 Outer reinforcement rib
10 Inner surrounding rim
11 Opening
12 Peripheral profile
13 Groove
14 Top side
15 Water
16 Water jet
17 Water flow
18 Capillary effect
19 Water discharge
20 Length, diameter
21 Effective length
22 Rounded end shape
23 Drop
100 Electronic control unit (ECU)

1. A housing for an electronic circuitry assembly, the housing comprising:
a housing cover and a base plate, the base plate having at least two outer reinforcement ribs at an inner surrounding rim;
a surrounding sidewall of the housing cover positioned at a free end of the surrounding sidewall between the at least two outer reinforcement ribs and the inner surrounding rim, of the base plate thereby defining a gap between the free end of the surrounding sidewall and the at least two outer reinforcement ribs on the base plate;
a plurality of openings formed in the base plate, the plurality of openings positioned between the at least two outer reinforcement ribs and the inner surrounding rim of the base plate, and wherein the free end of the surrounding sidewall covering the plurality of openings at least partially.

2. The housing of claim 1, wherein the plurality of openings are distributed around the inner surrounding rim of the base plate.

3. The housing of claim 1, wherein the free end of the surrounding sidewall has a peripheral profile.

4. The housing of claim 3, wherein the peripheral profile is plain.

5. The housing of claim 3, wherein the peripheral profile has a groove formed therein.

6. The housing of claim 1, wherein the plurality of openings are formed by a punching process.

7. The housing of claim 1, wherein the plurality of openings have an oblong form.

8. The housing of claim 1, wherein the plurality of openings have a rectangular form.

9. The housing of claim 1, wherein the plurality of openings have a round form.

10. The housing of claim 1, wherein the electronic circuitry assembly is an electronic control unit.

11. A housing for an electronic circuitry assembly, the housing comprising:
a housing cover and a base plate;
a surrounding sidewall of the housing cover, wherein a gap is defined between the surrounding sidewall and the base plate, wherein the base plate has at least two outer reinforcement ribs at an inner surrounding rim; and
a plurality of openings formed in the base plate, wherein the surrounding sidewall covers the plurality of openings at least partially, wherein the plurality of openings is positioned between the at least two outer reinforcement ribs and the inner surrounding rim of the base plate.

12. The housing of claim 11, wherein the plurality of openings is distributed around the inner surrounding rim of the base plate.

13. The housing of claim 11, wherein a free end of the surrounding sidewall has a peripheral profile.

14. The housing of claim 11, wherein the plurality of openings has an oblong form.

15. The housing of claim 11, wherein the plurality of openings has a rectangular form.

16. A housing for an electronic circuitry assembly, the housing comprising:
a housing cover and a base plate, the base plate having a reinforcement rib at an inner surrounding rim;
a surrounding sidewall of the housing cover positioned at a free end of the surrounding sidewall between the reinforcement rib and the inner surrounding rim of the base plate to define a gap between the free end of the surrounding sidewall and the reinforcement rib on the base plate;
an opening formed in the base plate, the opening positioned between the reinforcement rib and the inner surrounding rim of the base plate, and wherein the free end of the surrounding sidewall covers the opening at least partially.

17. The housing of claim 16, wherein the opening has an oblong form.

18. The housing of claim 16, wherein the opening has a rectangular form.

19. The housing of claim 16, wherein the opening has a round form.

20. The housing of claim 16, wherein the electronic circuitry assembly is an electronic control unit.
